(19) United States
(12) Patent Application Publication
(10) Pub. No.: US 2026/0040501 A1
(43) Pub. Date: Feb. 5, 2026

(54) DEVICE FOR COOLING A DATA CENTER COMPUTER SERVER BY USING A PHASE CHANGE MATERIAL

(71) Applicant: SUN-ICE ENERGY PTE. LTD., Singapore (SG)

(72) Inventor: Jacques Mouchet, Les Clayes-sous-Bois (FR)

(21) Appl. No.: 19/103,756

(22) PCT Filed: Sep. 1, 2023
(86) PCT No.: PCT/EP2023/074097

§ 371 Date: Feb. 13, 2025

(30) Foreign Application Priority Data
Sep. 2, 2022 (FR) FR2208844

(51) Int. Cl. H05K 7/20

(52) U.S. Cl. CPC H05K 7/208; H05K 7/20718; H05K 7/20836

(57) ABSTRACT

The present invention relates to a cooling device (1) for at least a datacenter computer server, wherein said device (1) comprises:
a phase-change material (5) configured to exchange heat with at least one of the components of said server,
at least one heat exchanger (7) connected to a heat transfer fluid circuit (3);
   said device (1) being configured, on one hand, to cool at least one component of said server by storing heat generated by said component in the phase-change material (5) and, on the other hand, to release the heat stored in the phase-change material (5) via said heat exchanger (7).

The present invention relates to the field of servers of datacenters, in particular of the heat management of said servers, notably their cooling, inter alia by using a phase-change material.

Datacenters are usually a building or a space inside a building, designed to accommodate computer systems and associated components, such as telecommunication and storage systems.

Since the operations by the computer systems are technically, scientifically and/or commercially critical, a datacenter generally comprises redundant or backup components and infrastructure for power supply, data communication connections, environmental controls (for example air conditioning, fire suppression) and various security devices.

In addition, a datacenter must be operational 24/7. Thus, its functioning induces the consumption of vast amounts of electric and/or thermal energy.

“Consumption of thermal energy” means that it is necessary to use energy to regulate the temperature of the computer servers and/or of the datacenter, for example by cooling the air that flows into the computer servers with electrically powered air conditioning systems. This temperature regulation is compulsory to guarantee the functioning of the datacenter and of its components, no matter the country, either in temperature or tropical zone.

Thus, usually, air conditioning systems are configured to cool the ambient air and circulate it through the servers, generally from the front to the back of said server, thus to cool the components inside the server. In addition, to make this air circulation through the servers easier, ventilation means are usually located behind the servers. However, these ventilation means feature far from insignificant electrical consumption and maintenance costs (breakdowns, filter replacement . . . )

Furthermore, it is known to use renewable power supply sources, usually intermittent, such as photovoltaic panels, wind turbines, etc., in association with a power storage battery, but this solution of power storage by battery is costly and may induce electrical and fire hazards for high power equipment.

Thus, considering the always increasing number of datacenters in use, it is urgent to find solutions to reduce their power consumption, their carbon footprint and/or their operating cost, while maintaining the best possible functioning conditions for the servers of these datacenters.

Thus, the present invention proposes to solve at least one of the above-mentioned issues with a cooling solution that uses a phase-change material (PCM) advantageously associated with a renewable power supply source.

Thus, the present invention relates to a cooling device for at least a datacenter computer server, wherein said device comprises:
a phase-change material configured to exchange heat with at least one of the components of said server;
at least one heat exchanger connected to a heat transfer fluid circuit;
   said device being configured, on one hand, to cool at least one component of said server by storing heat generated by said component in the phase-change material and, on the other hand, to release the heat stored in the phase-change material via said heat exchanger.

Thus, the cooling device makes it possible to easily and quickly manage the heat in the components of the server by storing the thermal energy generated by said components in a phase-change material, and a delayed management of the thermal energy stored in said material, for example during periods where the management of calories is more ecological and/or cheaper.

Advantageously, the phase-change material is configured to directly exchange heat with at least one component of the computer server, which means that the heat transfer from the server component to cool to the phase-change material is made mostly by conduction. The phase-change material can then be directly in contact with the at least one component or through one or several intermediate thermally conductive items (for example a heat exchanger, thermal paste, a flange, etc.)

It shall be noted that the phase-change material can also indirectly exchange heat with at least one component of said server. “Indirect heat exchange” means that the heat exchange between a component and the phase-change material is made through a fluid, such as a gas (for example the air) or a liquid (for example water).

The cooling device is advantageously configured to cool a computer server rack. It shall be noted that each rack generally comprises storage components (or hard disks) and at least one hub and/or network switch. The association of each rack to a cooling device according to the invention makes it possible to optimize and customize the thermal management of the components of the rack, which makes it possible to improve the lifetime of said components and/or to minimize the power consumption to cool a computer server rack and its components.

According to a possible characteristic, the device comprises at least one renewable electrical energy source, such as a photovoltaic panel, a wind turbine, etc., configured to power components of said device, such as said heat transfer fluid circuit and its subcomponents.

According to a possible characteristic, the device comprises an electronic monitoring unit configured to monitor the release of the heat stored in the phase-change material, for example so that the release is a function of the power supply available from a renewable electrical energy source and/or of the price of the energy.

It shall be noted that the heat release, monitored by said unit, is advantageously delayed, which means that the moment where the phase-change material stores the heat and the moment where this heat is released or de-stored are distinct and independent moments, for example so that the release is a function of the power supply from a renewable electrical energy source and/or of the price of the energy, thus making it possible a cooling of the servers more ecologically and/or cheaper.

Thus, the invention makes it possible to delay the use of energy to cool the phase-change material at the most adequate moment. It is then possible to cool the phase-change material, hence to store frigories when the price of electricity is advantageous, for example in the night, and so to use the stored frigories to remove or at least reduce the power consumption in the day (when the price of electricity is generally higher).

According to another possible characteristic, the heat transfer fluid circuit is thermally coupled to a “heat pump” type circuit or to a refrigeration system. Advantageously, the heat transfer fluid circuit is configured to be connected to a heat sink that makes it possible to release the heat stored in the phase-change material. The “heat pump” type circuit or a refrigeration system are generally systems that require power to work.

According to a first possible embodiment of the invention, the device comprises a ventilation unit configured to circulate an air flow through said server to the phase-change material.

Advantageously, the ventilation unit is located in order to suck air out of the server. Sucking the air from the server notably requires that the ventilation unit is advantageously located at the rear side of the server, leaving the front side of the server easy to reach for various operations, in particular maintenance operations. Furthermore, the ventilation unit advantageously comprises at least one fan-motor assembly and an electric battery.

According to a possible characteristic of the first mode, the air flow from the ventilation unit is directed to at least a cooling unit comprising said heat exchanger and said phase-change material. For example, these cooling units have substantially the shape of a column. The air flow, cooled when flowing through the column of the cooling unit, is then exhausted into the ambient air of the building and/or of the server room, or (directly) directed to the air inlets of at least one computer servers.

According to another possible characteristic of the first mode, the heat exchanger of the cooling unit comprises:
a first structure where a conduit is designed for the heat transfer fluid of the heat transfer fluid circuit;
a second structure around the first structure and being configured to cool (by heat transfer to the phase-change material) the air flow from the ventilation unit;
   said first and second structures being configured so that there is a gap between said structures that define a housing where said phase-change material is positioned.

According to another possible characteristic of the first mode, the air flow from the ventilation unit flows through the cooling unit downward.

The air flow, warmed by the server, flows then through the cooling unit and, for example, through the column of said unit along its length, which promotes the transfer of heat from the air flow to the phase-change material.

According to another possible characteristic of the first mode, the heat transfer fluid circuit is configured so that the heat transfer fluid flows through the heat exchanger upward.

Advantageously, the phase-change material is first re-solidified at the level of the material located at the bottom of said cooling unit.

According to another possible characteristic of the first mode, the ventilation speed of the ventilation unit is configured so that the temperature (as measured by a sensor at an adequate position) of the air of the servers and/or of the components of said servers is substantially stable.

According to a second possible embodiment of the invention, the device comprises a heat conduction item that links at least one of the components of said server to the phase-change material.

The heat conduction item is, for example, a structure in thermal contact, for example through a thermal paste, with a component whose temperature has to be lowered. For example, said heat conduction item is made of material with good heat conduction, such as a metal, for example copper, aluminum, etc.

According to another possible characteristic of the second mode, the heat conduction item further comprises a Peltier thermoelectric module.

A Peltier thermoelectric module makes it possible to accelerate the decrease of temperature of the component and to improve, possibly to force, the heat transfer to the phase-change material.

According to another possible characteristic of the second mode, the phase-change material is housed in said heat exchanger connected to the heat transfer fluid circuit.

According to another possible characteristic of the second mode, the heat exchanger comprises:
a first structure where a conduit is designed for the heat transfer fluid of the heat transfer fluid circuit;
a second structure around the first structure, in contact with at least one component of the server, and being configured to cool (by heat transfer to the phase-change material) the at least one component of the server;
   said first and second structures being configured so that there is a gap between said structures that define a housing where said phase-change material is positioned.

According to another possible characteristic, the device comprises a heat transfer fluid circuit comprising at least a pump and a heat exchanger associated with a refrigerant fluid circuit, for example configured to work in a “heat pump” mode.

According to another possible characteristic, the device comprises at least two temperature sensors from the following list: a temperature sensor for the air flow at the outlet of the server, a temperature sensor for the air flow at the inlet of the cooling unit, a temperature sensor for the air flow at the outlet of the cooling unit, a temperature sensor for the phase-change material, a measurement device for the latent heat loading rate (solidification) of the phase-change material, such as a temperature sensor and/or a pressure sensor.

According to another possible characteristic, the monitoring electronic unit is configured to monitor the “heat pump” type circuit, the heat transfer fluid circuit, the ventilation unit and/or the cooling device.

In particular, said monitoring unit is configured to monitor the flowrate of heat transfer fluid through said circuit, the flowrate of fluid through the “heat pump” type circuit, any item of the cooling device and/or the flowrate of air through the ventilation unit, etc.

Advantageously, said monitoring unit is configured to adjust the flowrate parameters of at least one fluid (air, heat transfer fluid, etc.) according to the real time power consumption of the server or of one of the racks of said server in order to stabilize the temperature of the server or of one of its items.

According to a second possible embodiment of the invention, all the exothermic items of the rack are directly mounted on the cooling units that contain some phase-change material and/or on the conduit for the heat transfer fluid.

This configuration is valid for new designs of autonomous racks including an integrated cooling system. The phase-change material makes it possible to store heat directly in the rack for future release without requiring strong ventilation. The other weakly exothermic items can be cooled by convection or with a slight ventilation at low power.

The invention also relates to the use of heat sinks to optimize the “reloading” (generally the solidification by cooling) of the phase-change materials according to the presence of collected intermittent energy. In case of long-term absence of such intermittent energy, the cooling unit will be directly powered by the mains.

It shall be noted that it is advantageously possible to cool and solidify the PCM around 15° C. (non limitatively) to simultaneously condense and remove any excessive moisture from the cooling air flow, without any restriction for other climatic conditions (from the desert to the pole).

In the case of direct cooling of the exothermic items, it is advantageously possible to use a phase-change material with solidification at ambient temperature around, non limitatively, 20° C. to 24° C., to prevent any condensation on the columns and in the racks.

It shall be noted that any refrigerant fluid can be used to cool the phase-change material, including a cooled water network (or any other gas or liquid) from a heat pump, or any other cooling means, including by Peltier effect.

The invention shall be better understood, and other goals, details, features and advantages shall appear more clearly in the following description of specific embodiments of the invention, which are introduced only for information and non-restrictively, with reference to the appended picture, where:

FIG. 1, referenced as FIG. 1, is a very schematic view of a cooling device according to the invention, designed for the thermal regulation of at least one server;

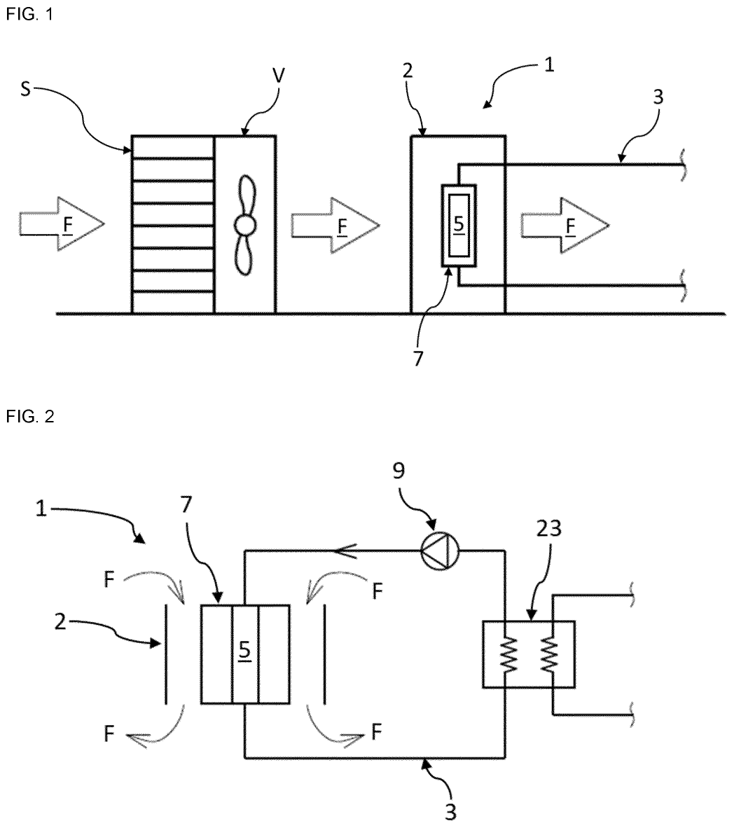

FIG. 2, referenced as FIG. 2, is a very schematic view of a cooling device according to an embodiment of the invention;

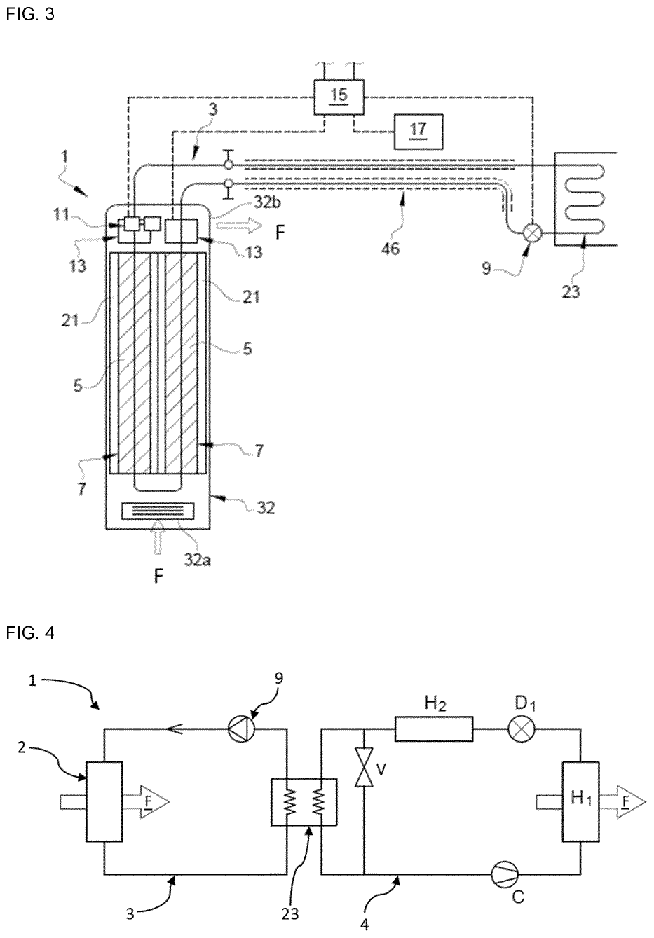

FIG. 3, referenced as FIG. 3, is a schematic and partial view of a cooling unit in a cooling device according to an embodiment of the invention;

FIG. 4, referenced as FIG. 4, is a very schematic view of a cooling device according another embodiment of the invention;

FIG. 4, referenced as FIG. 4, is a schematic perspective view of the heat exchanger of the cooling unit of FIG. 4;

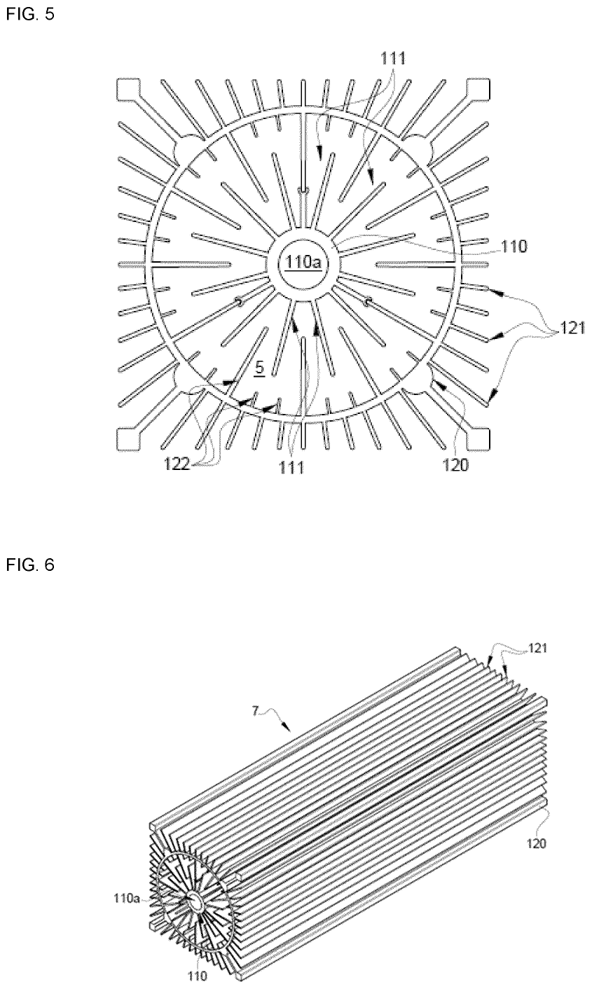

FIG. 5, referenced as FIG. 5, is a schematic cross-section of the heat exchanger of FIG. 4.

Furthermore, it shall be noted that on the various figures, the same references refer to identical or similar items.

The FIG. 1 is thus a very schematic and partial view of a cooling device 1 according to a first embodiment, designed to cool at least one server S or group of computer servers (where the servers may comprise one or several “racks”) for a datacenter.

The device 1 according to the invention can be adapted to cool each server S and/or collectively cool a set of servers without restriction of the number of servers.

Said device 1 comprises at least one cooling unit 2 and a ventilation unit V configured to circulate an air flow F through said at least one server S until the cooling unit 2.

For example, the ventilation unit V comprises at least one fan and/or a fan-motor assembly, including at least a fan located in order to suck air through said at least one server S, for example by being located at the rear of said at least one server S. The ventilation unit V can also comprise at least one battery to power the at least one fan and/or fan-motor assembly, in particular in case of possible power failure and/or to use electricity previously produced and stored at a lower cost (or more ecological).

Thus, said cooling device 1 comprises:
a phase-change material 5 configured to exchange heat (here thanks to the air flow F) with at least one of the components of said at least one server S;
at least one heat exchanger 7 connected to a heat transfer fluid circuit 3.

In particular, FIG. 1 show an embodiment of the invention, where the device 1 comprises the cooling unit 2 that houses the heat exchanger 7 connected to the heat transfer fluid circuit 3 and the phase-change material 5.

Said device 1 being configured, on one hand, to cool at least one component of said server S by storing heat generated by one of said components of the server S in the phase-change material 5 and, on the other hand, to release the heat stored in the phase-change material 5 via said heat exchanger 7 (and via the heat transfer fluid circuit 3).

Here, the heat transfer is achieved thanks to the air flow F through the server S, which yields calories to the air flow F (hence warms it), then the air flow F yielding its calories through the heat exchanger 7 to the phase-change material 5.

It shall be noted that a phase-change material 5 (PCM) is a material able to change of physical state in a restricted temperature range (latent heat) and to store and release calories this way.

Said phase-change material 5 has advantageously a fusion temperature between −10° C. and 25° C. (for the storage of energy), preferably between −5° C. and 20° C., and even more preferably between 12° C. and 18° C. or 18° C. and 28° C. in the case of the direct cooling as explained below.

FIG. 2 show a very schematic and partial view of an embodiment of the cooling device 1, where the cooling unit 2 is substantially shaped as a column, which houses the heat exchanger 7 connected to the heat transfer fluid circuit 3 and the phase-change material 5. It shall be noted that the device 1 may comprise one or several cooling units 2.

Said cooling unit 2 is thus so configured that the air flow F from the ventilation unit V is directed through the cooling unit 2, wherein the air flow is cooled when flowing through the column of the cooling unit 2 and is then exhausted into the ambient air of the building and/or of the server room, or (directly) directed to the air inlets of at least one computer servers. It shall be noted that the air flow from the ventilation unit V preferably flows through the cooling unit 2 downward.

The heat transfer fluid circuit 3 comprises a pump 9 configured to circulate the heat transfer fluid through said circuit 3, in particular through the heat exchanger 7 of the cooling unit 2, preferably upward, and another heat exchanger 23, called coupling exchanger, which is thermally coupled to a (not pictured) heat sink.

Thus, the heat transfer fluid circuit 3 is connected to a heat sink that makes it possible to release some heat stored in the phase-change material 5 thanks to the heat transfer fluid.

FIG. 3 is a schematic cross-sectional view of an embodiment of a cooling unit 2 of the device 1 of FIGS. 1 and 2.

Thus, the heat transfer fluid circuit 3 comprises:
the pump 9 to circulate the heat transfer fluid through said circuit 3;
a shut-down valve 11, said valve 11 being configured to stop the flow of the heat transfer fluid through said circuit 3; shutting down the circulation of the heat transfer fluid restricts or stops the storage or release of calories between the heat transfer fluid and the phase-change material 5;
at least one additional and facultative means of circulation 13 of the air flow, wherein said means of circulation 13 is configured to circulate the air flow F along said heat exchanger 7.

It should be noted that the heat transfer fluid is advantageously water, water glycol (which means a mixing of water and glycol), glycol, etc., but can also be a refrigerant fluid.

The additional means of circulation 13 is, for example, a fan-motor assembly or a fan (i.e. a centrifugal fan) that makes it possible to suck (or “push”) air through the unit 2 and circulate the air along the heat exchanger 7 so that it cools or warms up thanks to it (and by extension the room where the air flows in).

According to not pictured embodiments, the heat exchanger 7 can have different geometries and/or comprise various items so that air can flow at the center and/or at the edges of said heat exchanger 7.

The unit 2 further comprises a case 32 where are located, for example, the heat exchanger 7, the means of circulation 13, a part of the circuit 3, the shut-down valve 11, etc.

Said case 32 also comprises an air inlet 32a and an air outlet 32b to allow the air circulation thanks to said additional means of circulation 13 and/or of the ventilation unit V. Furthermore, it should be noted that the air inlet 32a can be configured to suck air from the outside (generally dry) and/or air already thermally conditioned by the unit 2 (also called recycled air).

Advantageously, a part of the circuit 3 that is not in the case 32 is thermally isolated from the outside, for example thanks to a thermal insulation 46. This thermal insulation restricts thermal losses before the heat transfer fluid reaches the phase-change material 5 (this is all the more relevant than the loop is big out of the case).

In addition, said unit 2 can also comprise a sheath, where said heat exchanger 7 is preferably located, wherein said sheath 21 is advantageously made of a thermally isolating material.

Said unit 2 also comprises:
a electronic monitoring unit 15 configured to monitor, inter alia, the circulation of the heat transfer fluid through said circuit 3 and/or the circulation (flow, speed, etc.) of the air flow through the unit 2 and/or through said at least one server S (hence to monitor the ventilation unit V and/or the additional means of circulation 13);
a human-machine interface 17, said human-machine interface (or user interface) being all the items that allow the user to interact with the unit, more specifically to monitor the unit and/or to exchange information with it.

The human-machine interface comprises, for example, one or several of the following items: button(s), keyboard, screen, touchscreen, knob(s), indicator lights, etc.

FIG. 4 shows a very schematic and partial view of a device 1 according to another variant of the first embodiment of the invention, wherein the heat sink (of the device 1 in FIG. 2) is a circuit of the “heat pump” type 4. Then, said device 1 comprises a heat pump type circuit 4 (through which flows, for example, a refrigerant fluid) that is thermally coupled to the heat transfer fluid circuit 3 via the heat exchanger 23.

Said heat pump type circuit 4 further comprises: a compressor C, a pressure regulator D₁, a heat exchanger H₁ (working, for example, as a, evaporator) and a heat exchanger H₂ (working, for example, as a condenser). Said circuit 4 also advantageously comprises a bypass branch that comprises a straight way valve V of the coupling heat exchanger 23. Said circuit 4 and its various items are thus configured to achieve a thermodynamic cycle to receive calories from the heat exchanger 23 (hence from the heat transfer fluid) and to evacuate them at the heat exchanger H₁, for example by yielding them to an air flow F through said heat exchanger H₁.

In another not pictured embodiment, said coupling heat exchanger 23 is coupled to a refrigeration system, through which flows, for example, a refrigerant fluid.

However, it shall be noted that no matter the variant or the embodiment, and without inducing any technical issue, said unit 2 can comprise at least two (not figured) temperature sensors from the following list: a temperature sensor for the air flow at the outlet of the server, a temperature sensor for the air flow at the inlet of the cooling unit, a temperature sensor for the air flow at the outlet of the cooling unit, a temperature sensor for the phase-change material, a measurement device for the latent heat loading rate (solidification) of the phase-change material, such as a temperature sensor and/or a pressure sensor.

Thus, the electronic monitoring unit 15 is advantageously configured to monitor: the “heat pump” type circuit, the heat transfer fluid circuit, the ventilation unit, the additional means of circulation and/or the cooling device.

In particular, said electronic monitoring unit 15 can be configured to monitor the flowrate of heat transfer fluid through said circuit 3, the flowrate of fluid (for example of refrigerant fluid) through the “heat pump” type circuit 4 and/or the flowrate of air through the ventilation unit V, etc. and as a rule any item of the cooling device.

As more specifically illustrated at FIGS. 5 and 6, which are respectively a cross-sectional view and a perspective view of the heat exchanger 7, this heat exchanger 7 comprises:
a first structure 110 where a conduit 110a is designed for the heat transfer fluid, for example at the center;
a second structure 120 around the first structure 110 (hence around the conduit 110a), for example concentric relatively to the first structure 110.

Said first 110 and second 120 structures are configured so that there is a gap between said structures 110 and 120 that defines a housing where the phase-change material 5 is positioned (or stored).

Furthermore, it should be noted that the heat exchanger 7 and its first and second structures 110 and 120 are advantageously made as independent columns in a metallic thermally conductive material, such as aluminum. The number and the size of the columns depends on the energy needed to deal with the intermittence of the one or several power supply sources.

The heat exchanger 7 is manufactured, for example, by extrusion. Furthermore, the heat exchanger 7 has preferably an elongated shape, so that the conduit for the heat transfer fluid is as long as possible, thus yielding to or recovering calories from the phase-change material 5.

Thus, according to a possible embodiment, the heat exchanger 7 comprises two aluminum extruded profiles 110 and 120 that are positioned concentric relatively to each another. For example, each of the profiles has circular, square, rectangle cross-sections, etc. The first extruded profile, resp. the first structure 110, comprises at its center the conduit 110a of the heat transfer fluid.

Thus, the air flow F is cooled and/or warmed up thanks to the second structure 120 of said heat exchanger 7, in particular through its outer surface. In addition, the structures 110 and 120 advantageously comprise fins 111, 121 and 122, wherein said fins make it possible to increase the contact surfaces, thus maximize thermal exchanges.

In particular, the fins 111 of the first structure 110 extend away toward the second structure 120 of said heat exchanger 7, thus the fins 111 extend into the volume or space where the phase-change material 5 is stored, which increases the contact surface between said material 5 and the first structure 110, and promotes thermal exchanges between the heat transfer fluid F through the conduit 110a and said material 5.

On the other hand, the fins 121 and 122 of the second structure 120 can extend away from the second structure 120 (from its outer surface)—they will be called external fins 121—and/or extend toward the first structure 110 (from the inner surface of the structure 120)—they will be called internal fins 122.

External fins 121 increase the contact surface between the thermal regulation flow F (in this case an air flow) and the second structure 120, which promotes thermal exchanges, while internal fins 122 increase the contact surface with the phase-change material 5, which promotes thermal transfer between the material 5 and the heat transfer fluid and/or the air flow F.

It should be noted that some fins 111 of the first structure 110 and the internal fins 122 are configured to cooperate with each other to secure a constant gap between said structures 110 and 120 and a good mechanical resistance of the set.

It should also be noted that the sheath 21 specifically encircles said at least one heat exchanger 7 so that there is a gap between the inner surface of the sheath 21 and the second structure 120 of said heat exchanger 7, wherein the gap created this way defines a conduit for the thermal regulation fluid F, such as air, and makes it possible to directed it and maximize thermal exchanges between the air flow F and the heat exchanger 7.

Advantageously, the outer perimeter defined by the external fins 121 has a geometric shape, such as a square or rectangle shape, which makes the manufacture easier for a sheath 21 to put onto the heat exchanger 7.

No matter the variant or the embodiment of the invention, the device 1 advantageously comprises at least one renewable electrical energy source, such as a photovoltaic panel, a wind turbine, etc., configured to power items of said device 1, such as said heat transfer fluid circuit 3 and its subcomponents.

The device comprises an electronic monitoring unit configured to monitor the release of the heat stored in the phase-change material, for example so that the release is a function of the power supply available from a renewable electrical energy source and/or of the price of the energy.

In another not pictured embodiment, called second mode, the phase-change material 5 is configured to directly exchange heat with at least one component of the computer server S, which means that the heat transfer from the server S component toward the phase-change material 5 is made mostly by conduction.

The phase-change material 5 can then be directly in contact with the at least one component or through one or several intermediate thermally conductive items (for example a heat exchanger, thermal paste, a flange, etc.).

Thus, in this second embodiment of the invention, the device 1 comprises a heat conduction item that links at least one of the components of said server S to the phase-change material 5.

The heat conduction item is, for example, a structure in thermal contact, for example through a thermal paste, with a component whose temperature has to be lowered. For example, said heat conduction item is made of material with good heat conduction, such as a metal, for example copper, aluminum, etc.

The heat conduction item can further comprise a Peltier thermoelectric module.

However, the phase-change material 5 is always advantageously housed in a heat exchanger connected to the heat transfer fluid circuit 3.

Thus, in this second not pictured embodiment, the heat exchanger comprises:
a first structure where a conduit is designed for the heat transfer fluid of the heat transfer fluid circuit;
a second structure around the first structure, in contact with at least one component of the server, and being configured to cool (by heat transfer to the phase-change material) the at least one component of the server;

Said first and second structures being configured so that there is a gap between said structures that defines a housing where said phase-change material is positioned.

In addition, in the context of a variant of the second embodiment of the invention, all the exothermic components of the server S are directly mounted on the columns or cooling units that contain some phase-change material 5, wherein the cooling units are inside and are an integral part of the server (or at least of a rack thereof).

1. Cooling device for at least a datacenter computer server, wherein said device comprises:
a phase-change material configured to exchange heat with at least one of the components of said server;
at least one heat exchanger connected to a heat transfer fluid circuit;
said device being configured, on one hand, to cool at least one component of said server by storing heat generated by said component in the phase-change material and, on the other hand, to release the heat stored in the phase-change material via said heat exchanger.

2. Device according to the claim 1, characterized in that the device comprises at least one renewable electrical energy source configured to power the items of said device.

3. Device according to claim 1, characterized in that the device comprises an electronic monitoring unit configured to monitor the release of the heat stored in the phase-change material.

4. Device according to claim 1, characterized in that the heat transfer fluid circuit is thermally coupled to a “heat pump” type circuit or to a refrigeration system.

5. Device according to claim 1, characterized in that the device comprises a ventilation unit configured to circulate an air flow through said server to the phase-change material.

6. Device according to the claim 5, characterized in that the ventilation unit is located in order to suck air out of the server.

7. Device according to claim 5, characterized in that the air flow from the ventilation unit is directed to at least a cooling unit comprising said heat exchanger and said phase-change material.

8. Device according to claim 7, characterized in that the heat exchanger of the cooling unit comprises:
a first structure where a conduit is designed for the heat transfer fluid of the heat transfer fluid circuit;
a second structure around the first structure and being configured to cool (by heat transfer to the phase-change material 5) the air flow from the ventilation unit;
said first and second structures being configured so that there is a gap between said structures that define a housing where said phase-change material is positioned.

9. Device according to claim 7, characterized in that the air flow from the ventilation unit is directed through the cooling unit downward.

10. Device according to claim 7, characterized in that the heat transfer fluid circuit is configured so that the heat transfer fluid flows through the heat exchanger upward.

11. Device according to claim 1, characterized in that the device comprises a heat conduction item that links at least one of the components of said server to the phase-change material.

12. Device according to claim 11, characterized in that the heat conduction item further comprises a Peltier thermoelectric module.

13. Datacenter comprising at least one server with a cooling device according to claim 1.
